(19) United States
(12) Patent Application Publication
(10) Pub. No.: US 2012/0155167 A1
(43) Pub. Date: Jun. 21, 2012

(54) NON-VOLATILE STORAGE DEVICE, INFORMATION PROCESSING SYSTEM AND WRITE CONTROL METHOD OF NON-VOLATILE STORAGE DEVICE

(75) Inventor: Keiichi UEHARA, Tokyo (JP)

(73) Assignee: KABUSHIKI KAISHA TOSHIBA, Tokyo (JP)

(21) Appl. No.: 13/196,723

(22) Filed: Aug. 2, 2011

(30) Foreign Application Priority Data
Dec. 21, 2010 (JP) 2010-284656

(51) Int. Cl. G11C 16/10

(52) U.S. Cl. 365/185.03

(57) ABSTRACT

A non-volatile storage device has a non-volatile memory, a capacity determination part configured to determine whether data amount stored into the non-volatile memory exceeds a first threshold value, an area dividing determination part configured to provide a first storage area for writing one bit data to one memory cell and a second storage area for writing multiple bit data to one memory cell in storage areas of the non-volatile memory, a first write control part configured to write data into the first storage area by a first writing mode until the capacity determination part determines that the first threshold value has been exceeded, a data selector configured to select data that frequency of access does not reach a predetermined reference value among data stored into the non-volatile memory when the capacity determination part determines that the first threshold value has been exceeded, and a second write control part configured to temporarily save data selected by the data selector from the first storage area to write the saved data to the second storage area by a second writing mode.

### CROSS REFERENCE TO RELATED APPLICATIONS

This application is based upon and claims the benefit of priority from the prior Japanese Patent Application No. 2010-284656, filed on Dec. 21, 2010, the entire contents of which are incorporated herein by reference.

### FIELD

The present invention relates to a non-volatile storage device, an information processing system and a write control method of a non-volatile semiconductor memory.

### BACKGROUND

As a large-capacity storage device in place of a hard-disk drive (referred to as HDD, hereinafter), an SSD (Solid State Drive) has attracted attention. The SSD has become widespread due to drastic price down of NAND flash memory. The SSD has features of low power consumption, high physical-impact resistance, compact size and thickness, etc. superior to an HDD. Therefore, it is predicted that the SSD becomes widespread more and more from now on.

The price of NAND flash memory has been decreased lately. However, the unit price per bit of the NAND flash memory is much more expensive than that of an HDD. Therefore, the storage capacity of the NAND flash memory is increased by storing multilevel bits in one memory cell, in general.

However, the NAND flash memory has a limitation, in principle, on the allowable number of times of rewriting. Especially, the allowable number of times of rewriting is extremely decreased when multilevel bits are stored. Moreover, different voltages have to be supplied to each memory cell a plurality of times in order to store multilevel bits. This requires complex write control and hence a writing speed is lowered.

Given such a background, a technique has been proposed to perform writing with area selection between a writing area (an SLC area) in which only one bit is written and the other writing area (an MLC area) in which a plurality of bits are written, in one memory cell, depending on whether the frequency of rewriting is equal to or higher than a predetermined threshold value.

When the SLC and MLC areas are provided beforehand as described above, if data is written in the entire SLC area for fast writing, fast writing is impossible any more, even if there is a vacancy in the MLC area. In this case, data to be often accessed has to be written in an MLC area, which results in low access performance.

### BRIEF DESCRIPTION OF THE DRAWINGS

FIG. 1 is a block diagram schematically showing the configuration of a non-volatile storage device 1 according to one embodiment;

FIG. 2 is a block diagram showing one example of a detailed internal configuration of a controller 3 of FIG. 1.

FIG. 3 is a flowchart indicating one example of a writing process performed by a CPU 4 and a NAND controller 10;

FIG. 4 is a flowchart following to FIG. 3;

FIG. 5 is a view showing the transition of write mode in a NAND flash 2; and

FIG. 6 is a block diagram schematically showing the configuration of an information processing system according to the second embodiment.

### DETAILED DESCRIPTION

One embodiment will now be explained with reference to the accompanying drawings.

One aspect of a non-volatile storage device has a non-volatile memory capable of changing number of bits written to one memory cell, a capacity determination part configured to determine whether data amount stored into the non-volatile memory exceeds a first threshold value, an area dividing determination part configured to provide a first storage area for writing one bit data to one memory cell and a second storage area for writing multiple bit data to one memory cell in storage areas of the non-volatile memory, a first write control part configured to write data into the first storage area by a first writing mode until the capacity determination part determines that the first threshold value has been exceeded, a data selector configured to select data that frequency of access does not reach a predetermined reference value among data stored into the non-volatile memory when the capacity determination part determines that the first threshold value has been exceeded; and a second write control part configured to temporarily save data selected by the data selector from the first storage area to write the saved data to the second storage area by a second writing mode.

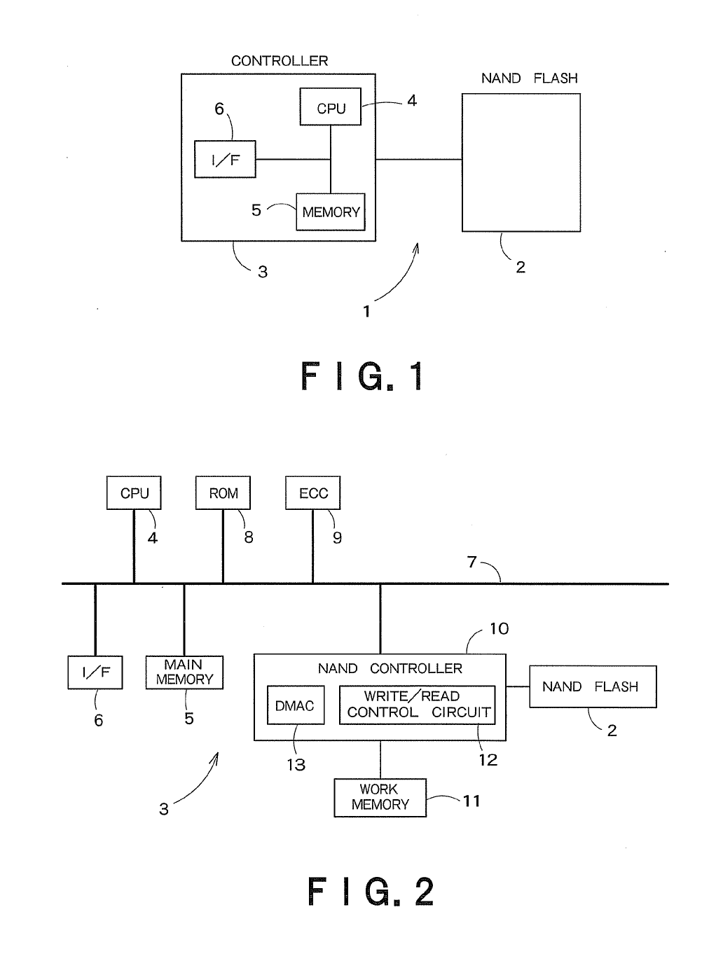

FIG. 1 is a block diagram schematically showing a configuration of a non-volatile storage device 1 according to one embodiment. The non-volatile storage device 1 of FIG. 1 in an SSD using a NAND flash memory (referred to as a NAND flash, hereinafter), for example.

In a NAND flash used in this embodiment, a plurality of write modes (cell modes) are selectable. Data can be written in the NAND flash by selecting one mode among, for example, an SLC (Single-Level Cell) mode, an MLC (Multi-Level Cell) mode, and a TLC (Triple-Level Cell) mode. The TLC mode is not inevitable in this embodiment. At least two modes of the SLC and MLC modes are enough in this embodiment. Described below as one example is a non-volatile storage device 1 having a built-in NAND flash for which one of three write modes including the TLC mode is selectable.

The write mode can be selected, for example, per block. The block is the unit of data erasure and in the range from, for example, about 512 KB to 2 MB. The write mode may be selected per page instead of block. The page is the unit of data for writing and reading, and is about 4 KB or 8 KB.

The SLC mode is a mode for writing 1-bit data in one memory cell. The SLC mode has features in which fast writing is possible and allowable number of times of data rewriting are large, but a total amount of data to be written in a NAND flash 2 is small. The MLC mode is a mode for writing multi-bit data (which is 2-bit data, hereinafter) in one memory cell. The MLC mode requires a more complex writing sequence than the SLC mode. Therefore, the MLC mode is slower in write speed and smaller in allowable number of times of data rewriting than the SLC mode. Nevertheless, The MLC mode has a feature in which a total amount of data to be written in the NAND flash 2 is large.

The present embodiment uses the NAND flash 2 having a plurality of selectable write modes and effectively utilize the advantages of both of the SLC and MLC modes to carry out fast writing and to increase a total data amount written to the NAND flash 2.

The non-volatile storage device 1 of FIG. 1 is provided with the NAND flash 2 and a controller 3. The controller 3 has a CPU 4, a main memory 5, an interface circuit (referred to as an I/F, hereinafter) 6. The controller 3 is usually configured with an LSI chip. However, the main memory 5 may be configured with a chip separated from the controller 3. The NAND flash 2 is provided as a memory module separated from the controller 3.

FIG. 2 is a block diagram showing one example of a detailed internal configuration of the controller 3 of FIG. 1. The controller 3 of FIG. 2 has the CPU 4 connected to a main bus 7, the main memory 5, the I/F 6, a ROM 8, an error correction circuit (referred to as an ECC, hereinafter) 9, a NAND controller 10, and a work memory 11 connected to the NAND controller 10.

The CPU 4 reads out a firmware program from the ROM 8 and loads the program into the main memory 5 to execute the program. In accordance with instructions from the CPU 4, the NAND controller 10 mainly performs write and read control of the NAND flash 2. The NAND controller 10 has a write/read control circuit 12 and a DMA controller (DMAC) 13. The NAND controller 10 performs DMA transfer of data between the NAND flash 2 and the work memory 11.

The NAND flash 2 has a limitation on the number of times of rewriting each memory cell. The NAND flash 2 is rewritable, for example, about 100,000 times by the SLC mode described above. On the contrary, it is rewritable only about 10,000 times in the MLC mode, for example. For that reason, the CPU 4 and the NAND controller 10 control write addresses so that a particular memory cell is not often rewritten.

For this control, the main memory 5 is provided with a table that indicates which data is written in which address.

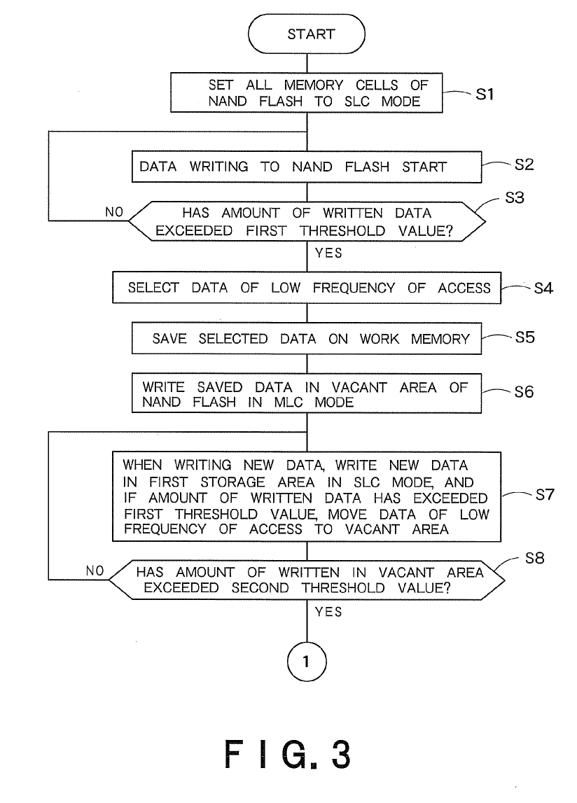

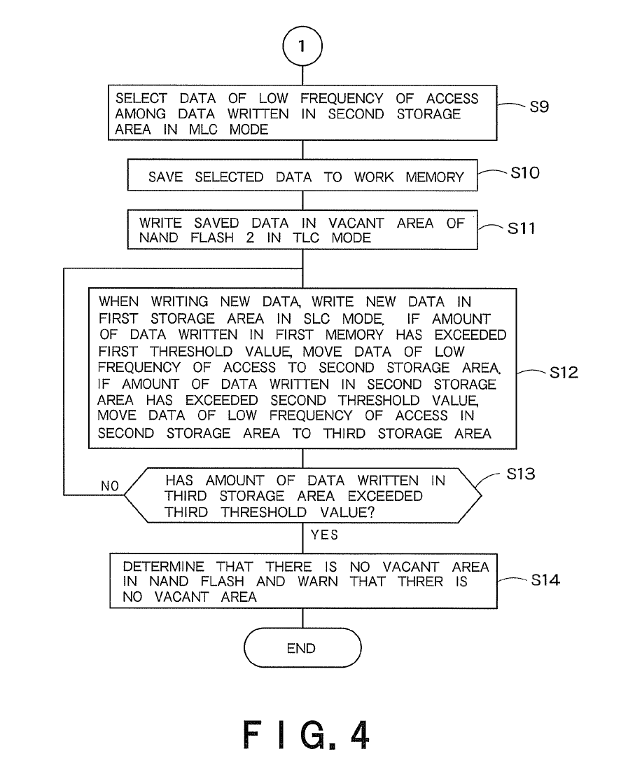

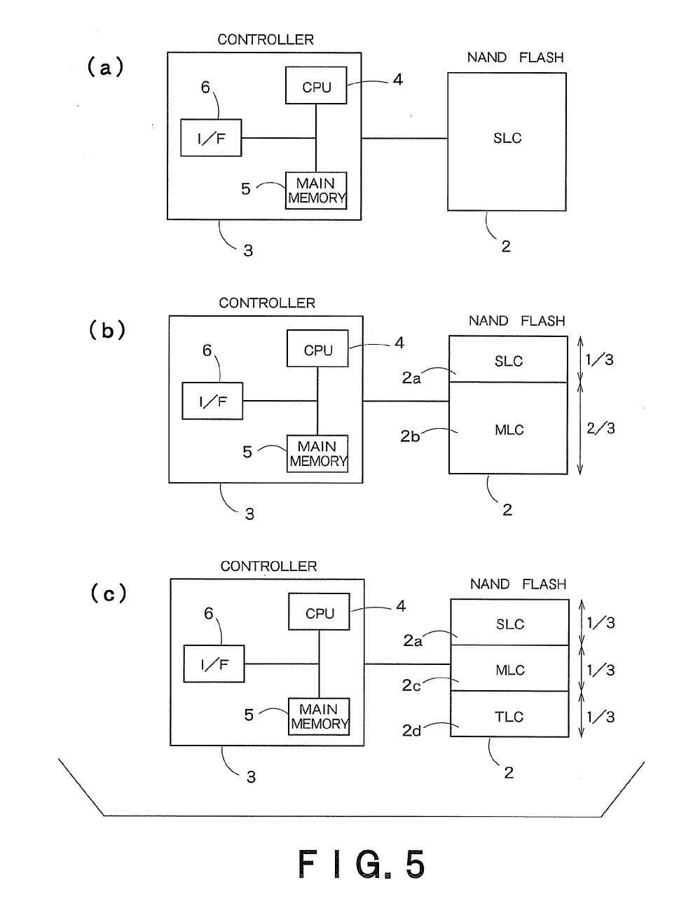

FIGS. 3 and 4 are flowcharts indicating one example of a writing process performed by the CPU 4 and the NAND controller 10. FIG. 5 is a view showing the transition of write mode in the NAND flash 2. The flowchart indicates processing steps by which data is written in the NAND flash 2 for the first time.

Firstly, as shown in FIG. 5(a), all memory cells of the NAND flash 2 are set to the SLC mode (step S1). The reason for setting to the SLC mode at first is as follows. The SLC mode allows fast writing and a large allowable number of times of rewriting. Therefore, it is preferable to set to the SLC mode when there is enough vacant memory capacity.

When data writing to the NAND flash 2 starts (step S2), it is determined whether the amount of written data has exceeded a first threshold value (step S3).

For the determination of step S3, a table stored in the main memory 5 is used. Registered in this table is the information that indicates which data has been written in which address. Therefore, by counting the number of times of registration, it can be determined whether the amount of written data has exceeded the first threshold value.

The first threshold value can be set to any appropriate value. For example, it is set to ⅓ of the entire memory capacity of the NAND flash 2. Therefore, data is written by the SLC mode up to ⅓ of the entire memory capacity of the NAND flash 2.

When it is determined in step S3 that the amount of written data has not exceeded the first threshold value, data writing is continued by the SLC mode with no mode change. And then, when the amount of written data is determined as exceeding the first threshold value, data of low frequency of access is selected among the data already written in the NAND flash 2 (step S4).

Whether the frequency of access is high or low is determined by the number of times of reading, for example. More specifically, a threshold value is provided to the number of times of reading per unit of page or block, and it is determined whether the number of times of reading has exceeded the threshold value per unit, in order to determine that the frequency of access is high or low. The number of times of reading data per unit is recorded registered in the table in the main memory 5, for example. In this way, the CPU 4 can easily and quickly determine the frequency of access when performing step S4 described above.

It is also preferable to determine whether the frequency of access is high or low according to an elapse time from when data is written in each memory cell lastly, instead of the number of times of reading. As an elapse time from when data is written in a memory cell lastly to any access (writing or reading) is longer, it indicates a lower frequency of access. It is therefore preferable to register information on the elapse time in the table of the main memory 5 described above and determine that the frequency of access is lower as the elapse time is longer. The CPU 4 operates on a system clock. Therefore, the information on the elapse time after data writing can be obtained with no much difficulty.

When data of low frequency of access is selected in step S4 described above, the selected data is once saved in the work memory 11 (step S5). After that, the saved data is written in a vacant area of the NAND flash 2 by the MLC mode (step S6).

Here, the vacant area is an area 2b of the NAND flash 2 other than an area (referred to as a first storage area 2a) thereof in which data has been written up to the first threshold value in the SLC mode. For example, if the first threshold value is ⅓ of the entire memory capacity, the vacant area is the remaining ⅔ area.

As described above, by performing step S6, the NAND flash 2 is divided into the area (the first storage area 2a) to be written by the SLC mode and the area 2b to be written in the MLC mode.

After that, when new data is to be written, the data is written in the first storage area 2a in the SLC mode. As a result of this, if the amount of written data has exceeded the first threshold value, a step of moving data of low frequency of access to a vacant area is performed (step S7). While this step is repeatedly performed, the amount of data written in the vacant area is gradually increased.

It is then determined whether the amount of data written in the vacant area has exceeded a second threshold value (step S8). The second threshold value can be set to any appropriate value. For example, it is set to ⅓ of the entire memory capacity of the NAND flash 2. Therefore, data is written in the first ⅓ (the first storage area 2a) of the entire memory capacity of the NAND flash 2 in the SLC mode, and then, written in the next ⅓ (a second storage area 2c) in the MLC mode.

When it is determined in step S8 that the amount of data written in the vacant area has not exceeded the second threshold value, the process moves to step S7 to perform data writing in the MLC mode. On the other hand, when it is determined that the data amount has exceeded the second threshold value, data of low frequency of access is selected among the data already written in the second storage area 2c by the MLC mode (step S9). Whether the frequency of access is high or low in step S9 is also determined by the number of times of reading registered in the table of the main memory 5 in the same way as step S4. The present embodiment assumes that the frequency of access to the first storage area 2a is higher than that to the second storage area 2c. Therefore, the frequency of access to be selected in step S9 is lower than that to be selected in step S4.

When data of low frequency of access is selected in step S9 described above, the selected data is once saved in the work memory 11 (step S10). After that, the saved data is written in a vacant area of the NAND flash 2 by the TLC mode (step S11).

The vacant area to be written in step S11 is an area (a third storage area 2d) other than the first and second storage areas 2a and 2c in the NAND flash 2. For example, if each of the first and second storage areas 2a and 2c is ⅓ of the entire memory capacity, the third storage area 2d is also ⅓ of the whole of the main memory 5.

With step S11, the NAND flash 2 is divided into the first, second and third storage areas 2a, 2c and 2d, as shown in FIG. 5(c).

After that, when new data is to be written, the new data is written in the first storage area 2a in the SLC mode. As a result of this, if the amount of written data has exceeded the first threshold value, data of low frequency of access is moved to the second storage area 2c. As a result of this, if the amount of data written in the second storage area 2c has exceeded the second threshold value, a step to move data of low frequency of access in the second storage area 2c to the third storage area 2d is performed (step S12). While this step is repeatedly performed, the amount of data written in the third storage area 2d is gradually increased.

It is then determined whether the amount of data written in the third storage area 2d has exceeded a third threshold value (step S13). The third threshold value is equivalent to the entire memory capacity of the third storage area 2d. It is, for example, ⅓ of the entire memory capacity of the NAND flash 2.

When the amount of data written in the third storage area 2d has not exceeded the third threshold value, data writing to the third storage area 2d is repeatedly performed. And, when it has exceeded the third threshold value, at this moment, it is determined that there is no vacant area in the NAND flash 2 and it is warned that there is no vacant area (step S14).

In the flow charts shown in FIGS. 3 and 4, steps S3, S8 and S13 correspond to a capacity determination part, steps S6, S7, S11 and S12 to an area dividing determination part, steps S1 to S3, S7 and S12 to a first write controller, step S4, S7, S9 and S12 to a data selector, and steps S5 to S7 and S10 to S12 to a second write controller.

As described above, in this embodiment, data writing is repeatedly performed by the SLC mode until the amount of data written in the NAND flash 2 exceeds the first threshold value, thereby realizing high-speed writing. When the data amount has exceeded the first threshold value, a data moving process is performed to automatically select data of low frequency of access and move data to be written by the MLC mode to the vacant area 2b. This moving process is performed as a background process after usual writing and reading processes end. Therefore, the moving process does not affect access performance to the NAND flash 2. With this moving process, a vacant area is created in an area to be written by the SLC mode (the first storage area 2a). Therefore, when new data is written after the moving process, it is also possible to perform high-speed writing to the first storage area 2a by the SLC mode.

After that, when data of low frequency of access are moved to a vacant area one by one, the amount of data written in the vacant area will exceed the second threshold value at some time. When this happens, in this embodiment, data of low frequency of access among data having been written in the second storage area 2c by the MLC mode is saved once in a vacant area (the third storage area 2d) by the TLC mode.

As described above, in order to write new data in the first storage area 2a by the SLC mode, data of low frequency of access are moved one by one and written in the second storage area 2c by the MLC mode. And, when the second storage area 2c becomes full, data of low frequency of access among data in the second storage area 2c are moved one by one and written in the third storage area 2d by the TLC mode. Therefore, writing by the SLC mode is always possible for the latest data and data of high frequency of access, thereby realizing high-speed writing. Moreover, data of low frequency of access are written by the MLC mode at first and then written by the TLC mode in order of low frequency of access when the amount of written data increases. Therefore, data of low frequency of access can be written in high density. In other words, by using the storage area of the NAND flash 2 at the maximum, as many data as possible can be stored. The MLC and TLC modes have a characteristic of low writing speed and small allowable number of times of data rewriting. However, in this embodiment, data of low frequency of access only is written by the MLC or TLC mode. Therefore, in this embodiment, low writing speed does not affect access performance so much and small allowable number of times of data rewriting is also almost not problematic.

Explained in the above embodiment is an example of providing the first, second and third storage areas 2a, 2c and 2d to be written in the SLC, MLC and TLC modes, respectively, each for ⅓ of the entire memory capacity of the NAND flash 2. This is, however, just one example. The storage areas can be divided freely. For example, when the first storage area 2a to be written by the SLC mode is provided larger than the second and third storage areas 2c and 2d, the frequency of moving data from the first storage area 2a to the second storage area 2c can be decreased, which may be more preferable.

Moreover, writing to the NAND flash 2 in either the SLC or MLC mode, without setting the TLC mode, can be done by dividing the storage area of the NAND flash 2 into the two first and second storage areas 2a and 2c, and selecting either of the modes and of the storage areas 2a and 2c.

Furthermore, when four or more of writing modes are provided, writing can be done by setting a storage area and a threshold value corresponding to each writing mode and performing the same writing process basically as the process shown in FIGS. 3 and 4.

### Second Embodiment

Described above in the first embodiment is an example of application to the non-volatile storage device 1 for an SSD or the like. In contrast, the second embodiment which will be described below is an example of application to an information processing system applicable to a PC or the like.

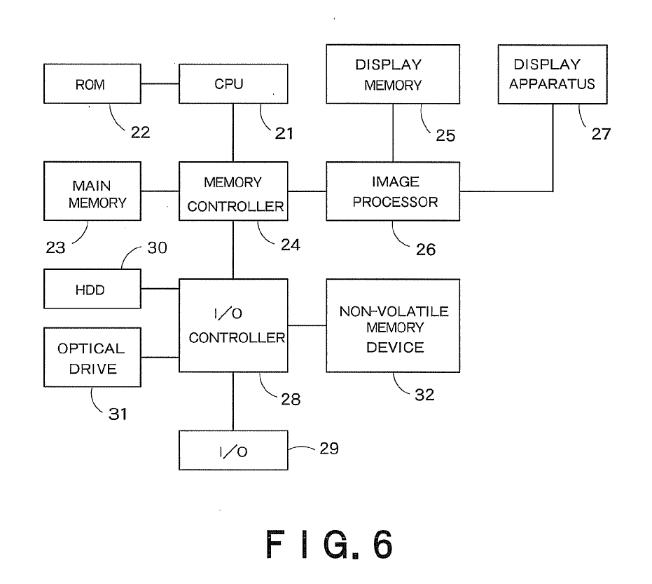

FIG. 6 is a block diagram schematically showing the configuration of an information processing system according to the second embodiment. The information processing system of FIG. 6 is a PC, for example. It retrieves an operating system (referred to as an OS, hereinafter) from an HDD and performs communications of information with several types of peripheral equipment connected to an I/F, under management by the OS.

An information processing system 20 of FIG. 6 is provided with a CPU 21, a ROM 22, a main memory 23, a memory controller 24, a display memory 25, an image processor 26, a display apparatus 27, an I/O controller 28, several types of I/O 29, an HDD 30, an optical drive 31, and a non-volatile storage device 32.

The non-volatile storage device 32 of FIG. 6 has the NAND flash 2 selectable among a plurality of writing modes, in the same way as the first embodiment. An SSD in conformity with an I/F such as Serial ATA may be used. In the non-volatile storage device 1 of FIG. 1, access to the NAND flash 2 is controlled by the controller 3. In contrast, for the non-volatile storage device 32 of FIG. 6, it is not required to have such an intelligent function as that of the controller 3 of FIG. 1. It is enough for the non-volatile storage device 32 to have a minimum function for access to the NAND flash 2.

In the second embodiment, the same process as FIGS. 3 and 4 is performed. The process is, however, not performed by a controller in the non-volatile storage device 32, but by the CPU 21 of the information processing system 20, which is different from the first embodiment.

The CPU 21 of FIG. 6 performs the same process as FIGS. 3 and 4 by executing a driver software that runs under management by the OS, for the non-volatile storage device 32. In other words, in the second embodiment, the process of FIGS. 3 and 4 is achieved by the driver software. Accordingly, there is no need to provide such an intelligent function as that of the controller 3 of FIG. 1 in the non-volatile storage device 32. Therefore, hardware cost can be reduced in the second embodiment. Moreover, the second embodiment can deal with a variety of problems that would occur when performing the process of FIGS. 3 and 4, and can also easily perform version-up of several types of functions.

It is preferable that the controller 3 in the non-volatile storage device 32 or other hardware in the information processing system 20 performs part of the process of FIGS. 3 and 4, instead of achieving the entire process with the driver software. In other words, it is preferable to perform the process of FIGS. 3 and 4 with the combination of hardware and software.

In FIG. 6, the non-volatile storage device 32 is provided separately from the HDD 30. However, the HDD 30 may be omitted. In this case, it is required to preinstall an OS program, a driver software, etc. in the non-volatile storage device 32.

As described above, in the second embodiment, the CPU 21 executes the driver software that runs under management by the OS to perform the process of FIGS. 3 and 4. Therefore, there is no need to provide the intelligent controller 3 that can perform the process of FIGS. 3 and 4 in the non-volatile storage device 32. The cost for the non-volatile storage device 32 can thus be reduced. Moreover, when any problem occurs in the steps of the process of FIGS. 3 and 4, or when functional version-up is required, version-up of the driver software can be done easily with an automatic version-up procedure provided by the OS. Therefore, maintenancebility is significantly improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the invention.

In the information processing system 20, when the process of FIGS. 3 and 4 is performed by the driver software, a program related to the software may be distributed via a communication network (including wireless communication) such as the Internet. The program may also be distributed via an online network such as the Internet or a wireless network, or stored in a storage medium and distributed under the condition that the program is encoded, modulated or compressed.

1. A non-volatile storage device comprising:
a non-volatile memory capable of changing the number of bits written to a memory cell;
a capacity determination module configured to determine whether a first data amount stored in the non-volatile memory exceeds a first threshold value;
an area dividing determination module configured to provide a first storage area in the non-volatile memory for writing single bit data to a first set of memory cells and a second storage area in the non-volatile memory for writing multiple bit data to a second set of memory cells;
a first write controller configured to write data to the first storage area using a first writing mode until the capacity determination module determines that the first threshold value has been exceeded;
a data selector configured to select a first subset of data from the data stored in the first storage area, wherein the first subset of data is associated with a frequency of access less than a predetermined reference value when the capacity determination module determines that the first threshold value has been exceeded; and
a second write controller configured to temporarily save the first subset of data for writing to the second storage area using a second writing mode.

2. The non-volatile storage device of claim 1, wherein when both the first write controller and the second write controller are attempting to perform a write, the first write controller is given priority.

3. The non-volatile storage device of claim 1, wherein:
the area dividing determination module is further configured to divide the non-volatile memory into at least three storage areas including the first storage area, the second storage area, and a third storage area for writing bit data exceeding the space available in the second storage area to a third set of memory cells;
the capacity determination module is further configured to determine whether a second data amount stored in the second storage area exceeds a second threshold value;
the data selector is further configured to select a second subset of data from the data stored in the second storage area, wherein the second subset of data is associated with a frequency of access less than a second reference value when the capacity determination module determines that the second threshold value has been exceeded, wherein the second reference value is less than the first reference value; and
the second write controller is further configured to temporarily save the second subset of data for writing to the third storage area using a third writing mode.

4. The non-volatile storage device of claim 1, wherein an access speed of the first storage area is faster than an access speed of the second storage area, and an allowable number of times for data rewriting in the first storage area is greater than an allowable number of times for data rewriting in the second storage area.

5. The non-volatile storage device of claim 4, wherein:
the access speed of the first storage area is faster than the access speed of the second storage area and the access speed of the second storage area is faster than an access speed of the third storage area; and
the allowable number of times for data rewriting in the first storage area is greater than the allowable number of times for data rewriting in the second storage area and the allowable number of times for data rewriting in the second storage area is greater than an allowable number of times for data rewriting in the third storage area.

6. The non-volatile storage device of claim 1, wherein:
the non-volatile memory is a NAND type flash memory;
the first storage area uses an SLC (Single-Level Cell) mode for write operations; and
the second storage area uses an MLC (Multi-Level Cell) mode for write operations.

7. The non-volatile storage device of claim 1, wherein:
the non-volatile memory is a NAND type flash memory;
the first storage area uses an SLC (Single-Level Cell) mode for write operations;
the second storage area uses an MLC (Multi-Level Cell) mode for write operations; and
the third storage area uses a TLC (Triple-Level Cell) mode for write operations.

8. The non-volatile storage device of claim 1, wherein the data selector is further configured to determine the frequency of access based on a number of reads of data stored in the non-volatile memory.

9. The non-volatile storage device of claim 1, wherein the data selector determines the frequency of access based on an elapsed time from when data is stored in the non-volatile memory to when the data is accessed next.

10. The non-volatile storage device of claim 1, further comprising a memory controller configured to control the non-volatile memory, the memory controller comprising:
a processor;
a work memory configured to store data for performing operations of the processor; and
an interface module configured to send and receive signals from a host apparatus,
the work memory further configured to store programs for executing operations of the capacity determination module, the area dividing module, the first write controller, the data selector, and the second write controller by the processor.

11. An information processing apparatus comprising:
a processor configured to execute an operating system at a start-up time, the processor capable of executing programs on the operating system;
a main memory accessed by the processor;
a memory controller configured to control access to the main memory;
a display controller configured to control the display of a display apparatus based on instructions from the processor;
a display memory configured to store image data displayed on the display apparatus;
an I/O controller configured to control peripheral apparatuses based on instructions from the processor; and
a non-volatile storage device controlled by the I/O controller,
wherein the non-volatile storage device comprises a non-volatile memory capable of changing the number of bits written to a memory cell; and
wherein the processor is further configured to:
determine whether a first data amount stored in the non-volatile memory exceeds a first threshold value;
provide a first storage area in the non-volatile memory for writing single bit data to a first set of memory cells and a second storage area in the non-volatile memory for writing multiple bit data to a second set of memory cells;
write data into the first storage area using a first writing mode until the first threshold value has been exceeded;
select a first subset of data from the data stored in the first storage area, wherein the first subset of data is associated with a frequency of access less than a predetermined reference value when the first threshold value has been exceeded; and
temporarily save the first subset of data for writing to the second storage area using a second writing mode.

12. The information processing apparatus of claim 11, wherein when the processor is performing a first write operation using the first writing mode and a second write operation using the second writing mode, the first write operation is given priority.

13. The information processing apparatus of claim 11, wherein:
the non-volatile memory is divided into at least three storage areas including the first storage area, the second storage area, and a third storage area for writing bit data exceeding the space available in the second storage area to a third set of memory cells;
the processor is further configured to:
determine whether a second data amount stored in the second storage area exceeds a second threshold value;
select a second subset of data from the data stored in the second storage area, wherein the second subset of data is associated with a frequency of access less than a second reference value in response to determining that the second threshold value has been exceeded, wherein the second reference value is less than the first reference value;
temporarily save the second subset of data for writing to the third storage area using a third writing mode.

14. The information processing apparatus of claim 11, wherein an access speed of the first storage area is faster than an access speed of the second storage area, and an allowable number of times for data rewriting in the first storage area is greater than an allowable number of times for data rewriting in the second storage area.

15. The information processing apparatus of claim 14, wherein:
the access speed of the first storage area is faster than the access speed of the second storage area and the access speed of the second storage area is faster than an access speed of the third storage area; and
the allowable number of times for data rewriting in the first storage area is greater than the allowable number of times for data rewriting in the second storage area and the allowable number of times for data rewriting in the second storage area is greater than an allowable number of times for data rewriting in the third storage area.

16. The information processing apparatus of claim 11, wherein:
the non-volatile memory is a NAND type flash memory;
the first storage area uses an SLC (Single-Level Cell) mode for write operations; and
the second storage area uses an MLC (Multi-Level Cell) mode for write operations.

17. The information processing apparatus of claim 11, wherein:
the non-volatile memory is a NAND type flash memory;
the first storage area uses an SLC (Single-Level Cell) mode for write operations;
the second storage area uses an MLC (Multi-Level Cell) mode for write operations; and
the third storage area uses a TLC (Triple-Level Cell) mode for write operations.

18. The information processing apparatus of claim 11, wherein the frequency of access is determined based on a number of reads of data stored in the non-volatile memory.

19. The information processing apparatus of claim 11, wherein the frequency of access is determined based on an elapsed time from when data is stored in the non-volatile memory to when the data is accessed next.

20. A write control method of controlling a non-volatile storage device comprising a non-volatile memory capable of changing the number of bits written to a memory cell, the method comprising:
determining whether a data amount stored in the non-volatile memory exceeds a first threshold value;
providing a first storage area in the non-volatile memory for writing single bit data to a first set of memory cells and a second storage area in the non-volatile memory for writing multiple bit data to a second set of memory cells;
writing data to the first storage area using a first writing mode until it is determined that the first threshold value has been exceeded;
selecting a subset of data from the data stored in the first storage area, wherein the subset of data is associated with a frequency of access less than a predetermined reference value when it is determined that the first threshold value has been exceeded; and
temporarily saving the subset of data for writing to the second storage area using a second writing mode.
